(19) United States
(12) Patent Application Publication
(10) Pub. No.: US 2012/0305771 A1
(43) Pub. Date: Dec. 6, 2012

(54) Proximity Sensor Packaging Structure And Manufacturing Method Thereof

(75) Inventor: Lu-Ming Lai, New Taipei City (TW)

(73) Assignee: EVERLIGHT ELECTRONICS CO., LTD., New Taipei City (TW)

(21) Appl. No.: 13/578,601

(22) PCT Filed: Feb. 10, 2011
(86) PCT No.: PCT/CN2011/070904

§ 371 Date: Aug. 10, 2012

(30) Foreign Application Priority Data
Feb. 12, 2010 (CN) 201010128176.7

(51) Int. Cl. H01L 31/16; H01L 31/18

(52) U.S. Cl. 250/338.4; 438/64; 257/E31.117

(57) ABSTRACT

The present invention pertains to a proximity sensor packaging structure, which comprises a substrate, two first electrically conductive layers and a plurality of second electrically conductive layers that are disposed on the substrate. The substrate has first and second grooves that are respectively defined by a bottom surface and an interior sidewall. Each electrically conductive layer extends from a bottom surface of the first groove, along the interior sidewall of the first groove and in an opposite direction relative to the other first electrically conductive layer, to an exterior sidewall of the substrate. The second electrically conductive layers include first and second electrically conductive portions. The first electrically conductive portion is disposed on a central region of the bottom surface of the second groove. The second electrically conductive portion extends from the bottom surface of the second groove, along the interior sidewall thereof, to the exterior sidewall of the substrate.

### CROSS-REFERENCE TO RELATED APPLICATION

This application is the U.S. national stage application of International Application No. PCT/CN2011/070904, filed on Feb. 10, 2011, which claims the priority benefit of Chinese Patent Application No. 201010128176.7, filed on Feb. 12, 2010. The above-identified patent applications are hereby incorporated by reference.

### BACKGROUND

1. Technical Field

The present invention relates to a proximity sensor packaging structure and manufacturing method thereof. More particularly, the present invention relates to a proximity sensor packaging structure having a sensor chip and a light-emitting chip, and manufacturing method thereof.

2. Description of Related Art

In recent days, infrared (IR) proximity sensors are being implemented in more and more applications such as mobile phones and portable devices. For example, one of such applications includes the control of an on/off switch of the display of a digital camera using an IR proximity sensor. When an object, such as a user's eye, is near a viewing window on the side of the IR proximity sensor, the IR proximity sensor detects the presence of the object and, in response, executes a command to turn off the display so as to save power from being consumed by the display.

Referring to FIG. 1, FIG. 1 shows a diagram of a conventional proximity sensor packaging structure. As shown in FIG. 1, a conventional proximity sensor packaging structure 10 is used to detect an object 12 that is within a specified distance d of the conventional proximity sensor packaging structure 10. The conventional proximity sensor packaging structure 10 includes an IR light-emitting diode (LED) chip 14, a sensor chip 16, a printed circuit board 18 and a translucent cover 20. The IR LED chip 14 and sensor chip 16 are respectively disposed on the printed circuit board 18 and are electrically connected externally. When the conventional proximity sensor packaging structure 10 begins to operate, light produced by the IR LED chip 14 and carrying a specific signal and is emitted upwardly in a divergent fashion and then reflected by the to-be-detected object 12 towards the sensor chip 16. The sensor chip 16, upon receiving the light carrying the specific signal, determines the object 12 is near. Moreover, the printed circuit board 18 includes a partition 22, disposed between the IR LED chip 14 and the sensor chip 16, to prevent the light emitted by the IR LED chip 14 and carrying the specific signal from being directly received by the sensor chip 16. Additionally, the translucent cover 20 covers over the IR LED chip 14, the sensor chip 16 and the printed circuit board 18 for protection.

However, as the light emitted by an IR LED chip is divergent and a translucent cover is partially reflective, some of the light emitted by the IR LED chip is reflected by the translucent cover and received by the sensor chip when the light travels through the translucent cover. Consequently, erroneous determination by the sensor chip may result due to interference of the light reflected from the object to be detected and the light reflected from the translucent cover. Furthermore, to prevent detection of light from the IR LED chip by the sensor chip before the light emits out of the packaging structure, the IR LED chip and the sensor chip are spaced apart as much as possible in conventional proximity sensor packaging structures, at the expense of enlarged size of the conventional proximity sensor packaging structures. Thus, in order to satisfy the trend of shrinkage in size of components and to avoid interference of light emitted from the IR LED chip by light reflected from the translucent cover, improvement in the structure of IR proximity sensor has been an objective in the industry.

### SUMMARY

A main objective of the present invention is to provide a proximity sensor packaging structure and manufacturing method thereof to resolve the aforementioned issues, and to improve the sensing capability of proximity sensor packaging structures.

To achieve the above-identified objective, the present invention provides a proximity sensor packaging structure, comprising: a non-translucent substrate, two first electrically conductive layers disposed on the substrate, a plurality of second electrically conductive layers disposed on the substrate, a light-emitting chip, a sensor chip and two encapsulation bodies. The substrate has a first groove and a second groove. The first groove and the second groove are defined by a bottom surface and a respective interior sidewall that extends from the bottom surface to a top surface of the substrate. The first electrically conductive layers are electrically insulated between one another. The first electrically conductive layers extend from a bottom surface of the first groove, along the interior sidewall of the first groove and in opposite directions, to an exterior sidewall of the substrate. The second electrically conductive layers are electrically insulated from each other. The second electrically conductive layers comprise a first electrically conductive portion and a second electrically conductive layer. The first electrically conductive layer is disposed at a central region of a bottom surface of the second groove. The second electrically conductive portion extends from the bottom surface of the second groove along the interior sidewall of the second groove to the exterior sidewall of the substrate. The light-emitting chip is disposed in the first groove and electrically connected between the first electrically conductive layers. The sensor chip is disposed in the second groove and electrically connected to the second electrically conductive layers. The encapsulation bodies are disposed over the light-emitting chip and the sensor chip.

To achieve the aforementioned objective, the present invention provides a method of manufacturing proximity sensor packaging structures. Firstly, a substrate is provided. The substrate has a first groove and a second groove. The substrate is non-translucent. Then, a plurality of patterned trenches are formed on one or more surfaces of the substrate. Portions of the substrate in the patterned trenches have a rough surface. Next, two first electrically conductive layers and a plurality of second electrically conductive layers are formed on the portions of the substrate that are in the patterned trenches. Afterwards, a light-emitting chip and a sensor chip are adhered to the substrate in the first groove and the second groove, respectively. The light-emitting chip is electrically connected between the first electrically conductive layers, and the sensor chip is electrically connected to the second electrically conductive layers.

Technical advantages provided by the present invention relative to existing techniques are as follows: The manufacturing method of a proximity sensor packaging structure of the present invention forms electrically conductive layers directly on a substrate, and disposes a light-emitting chip and a sensor chip on the substrate so that the light-emitting chip and the sensor chip are packaged in the same packaging structure to reduce the size of the proximity sensor. Moreover, as the substrate of the proximity sensor packaging structure of the present invention is non-translucent, erroneous detection of light emitted from the light-emitting chip, disposed in the first groove, and through the substrate by the sensor chip, disposed in the second groove, is prevented.

### BRIEF DESCRIPTION OF THE DRAWINGS

FIG. 1 is a diagram of a conventional proximity sensor packaging structure.

FIG. 2 through FIG. 6 are diagrams of a manufacturing method of a proximity sensor packaging structure in accordance with a first embodiment of the present invention.

FIG. 7 is a top view diagram of a proximity sensor packaging structure in accordance with a second embodiment of the preset invention.

FIG. 8 is a top view diagram of another implementation of the proximity sensor packaging structure in accordance with the second embodiment of the present invention.

FIG. 9 is a diagram showing object detection using a proximity sensor packaging structure in accordance with the present invention.

FIG. 10 is a top view diagram of a proximity sensor packaging structure in accordance with a third embodiment of the present invention.

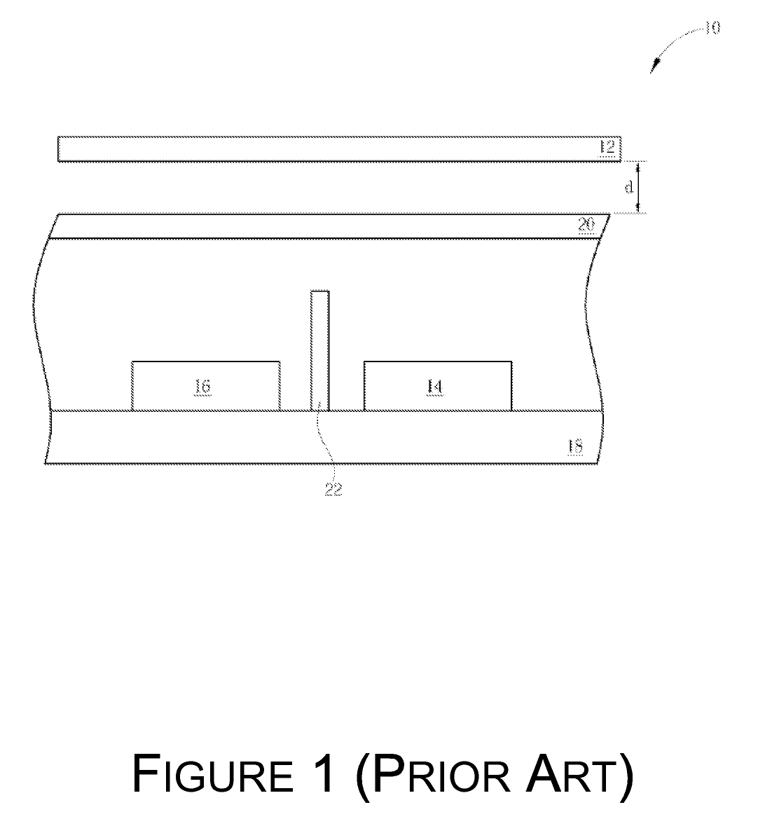

### DETAILED DESCRIPTION OF DISCLOSED EMBODIMENTS

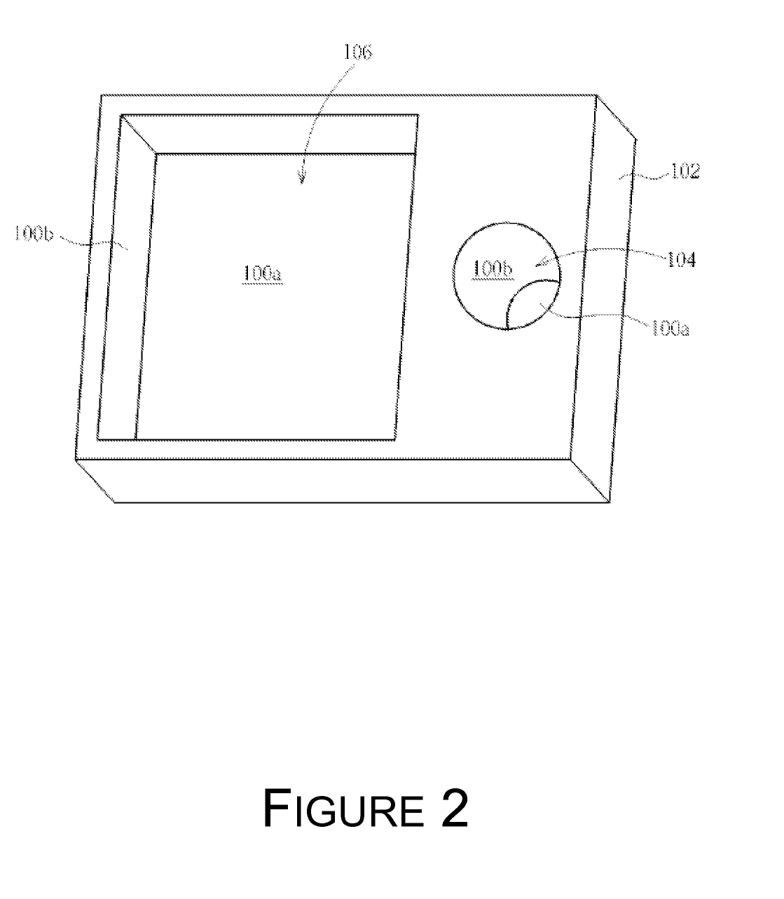

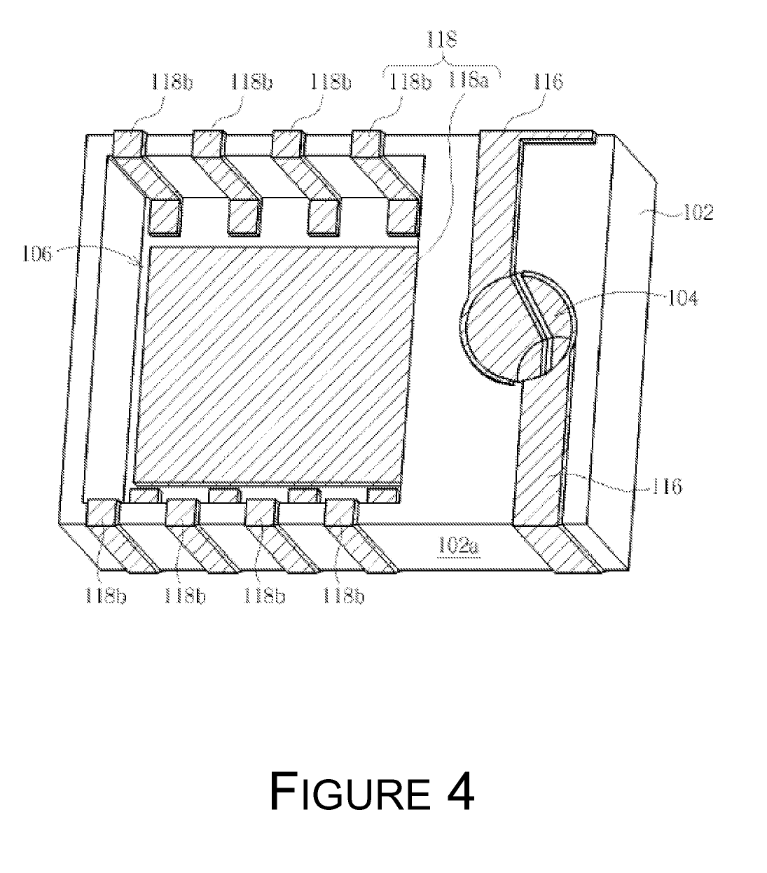

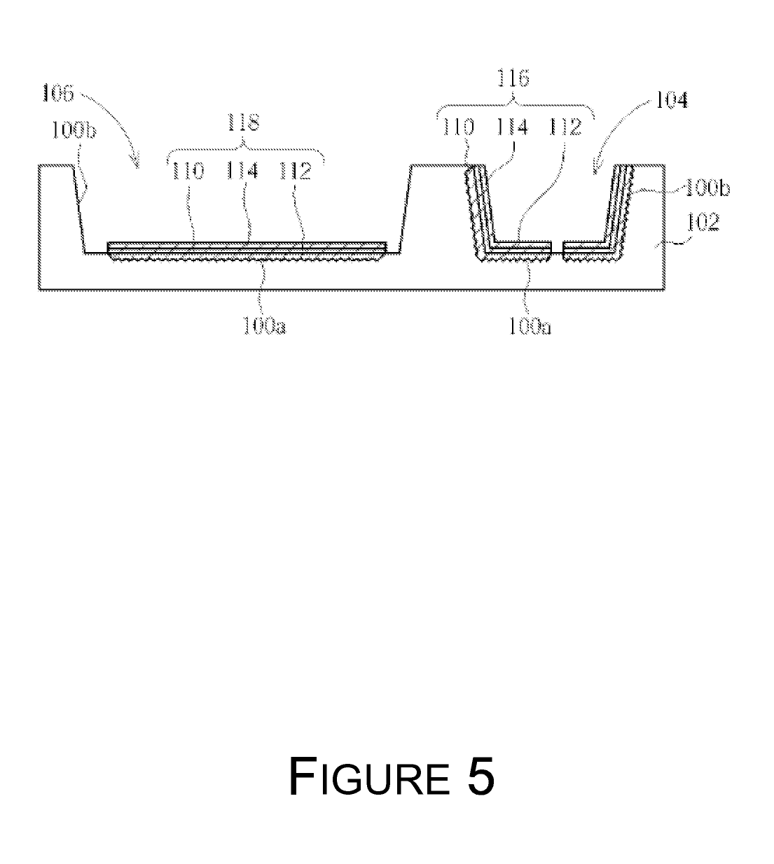

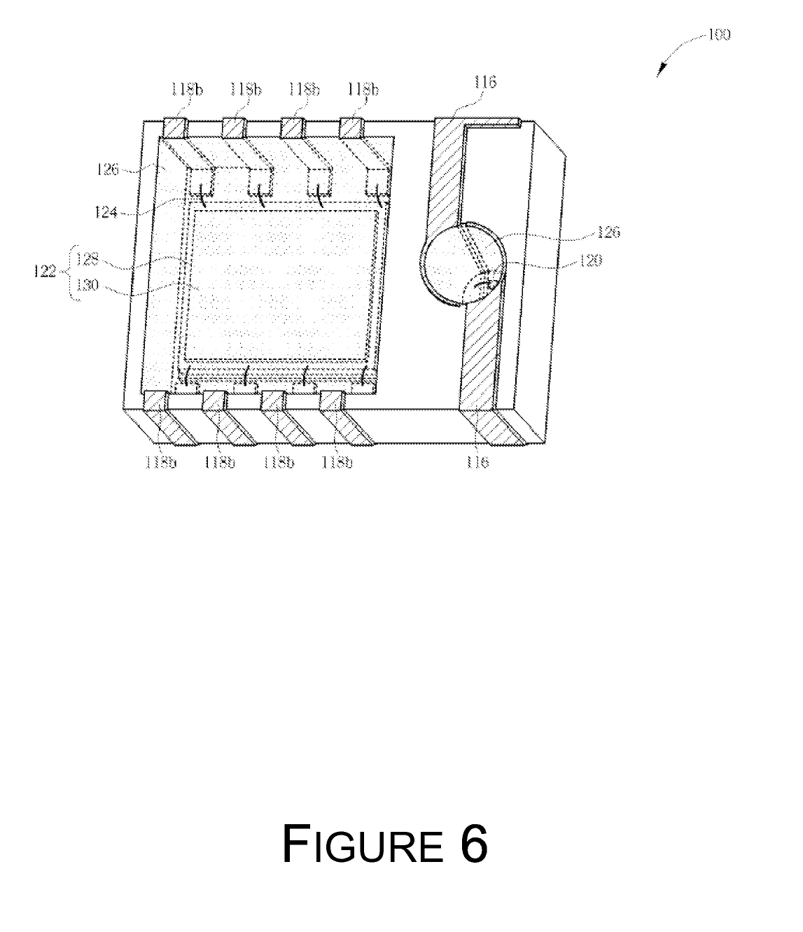

Referring to FIGS. 2-6, FIGS. 2-6 are diagrams of a manufacturing method of a proximity sensor packaging structure in accordance with a first embodiment of the present invention. FIG. 6 illustrates a side view of the proximity sensor packaging structure in accordance with the first embodiment of the present invention. As shown in FIG. 2, first, a substrate 102 is provided. The substrate 102 includes a first groove 104 and a second groove 106, which are defined by a bottom surface 100a and an interior sidewall 100b that extends from the bottom surface 100a to an upper surface of the substrate 102. In one embodiment, the first groove 104 is a groove of parabolic shape such as, for example, bowl-shaped but is not limited thereto. Additionally, the substrate 102 is non-translucent and made of a composite material such as, for example, polymide, thermoplastic polyester, crosslinked PBT, or liquid crystal polymer, etc. The composite material is laser activated so that one or more electrically conductive layers can be formed on one or more surfaces of the composite material during subsequent processing. Moreover, the composite material includes a dopant such as, for example, titanium dioxide, aluminum nitride, or zirconium dioxide. Upon activated by laser irradiation, the dopant becomes a metal catalyst. In one embodiment, the method for forming the substrate 102 is injection molding, but is not limited thereto. Other molding processing may be used to make the substrate 102.

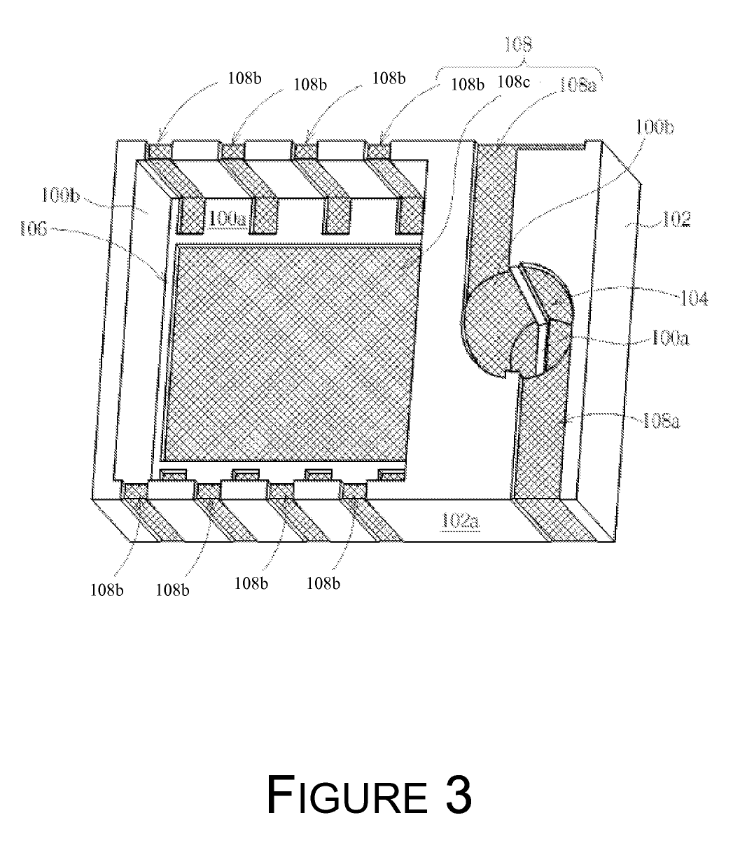

Next, as shown in FIG. 3, a laser activation process is performed by irradiating a laser beam directly on the surface of the substrate 102 to cause erosion of a part of the surface of the substrate 102 that is irradiated by the laser, thereby forming a plurality of patterned trenches. Meanwhile, the dopant on the surface of the substrate 102 is activated by the laser to become a metal catalyst. In one embodiment, the patterned trenches 108 can be divided into two first patterned trenches 108a, a plurality of second patterned trenches 108b, and a third patterned trench 108c. The first patterned trenches 108a extend from the bottom surface 100a of the first groove 104, along the interior sidewall 100b of the first groove 104 and in opposite directions, to an exterior sidewall 102a of the substrate 102. The second patterned trenches 108b extend from the bottom surface 100a of the second groove 106, along the interior sidewall 100b of the second groove 104, to the exterior sidewall 102a of the substrate 102. The third patterned trench 108c is disposed at a central region of the bottom surface 100a of the second groove 106. It is noteworthy that laser irradiation causes the substrate 102, in particular the portions of the substrate 102 located in the patterned trenches 108, to develop a rough surface.

Subsequently, as shown in FIGS. 3-5, an electroless plating process is performed, in which the substrate 102 is placed in a chemical plating solution with metal ions, so that metal ions on the portions of the substrate 102 in the patterned trenches 108 are reduced to metal atoms by the metal catalyst to form a first plating layer 110 on the portions of the substrate 102 in the patterned trenches 108. Through the rough surface of the substrate 102, the first plating layer 110 is embedded on the substrate 102 with enhanced adhesion to the substrate 102. Then, an electroplating process is performed to form a second plating layer 112 on the first plating layer 110. Afterwards, another electroplating process is performed to form a third plating layer 114 on the second plating layer 112 to form two first electrically conductive layers 116 and a plurality of second electrically conductive layers 118 on the portions of the substrate 102 in the patterned trenches 108. Each of the first electrically conductive layers 116 and each of the second electrically conductive layers 118 is respectively constructed of the first plating layer 110, the second plating layer 112, and the third plating layer 114. The first electrically conductive layers 116 are electrically insulated between one another. Each of the electrically conductive layers 116 is formed in a respective laser-activated first patterned trench 108a and thus has the same pattern as the respective first patterned trench 108a. That is, each of the electrically conductive layers 116 extends from the bottom surface 100a of the first groove 104, along the interior sidewall 100b of the first groove 104 and in an opposite direction relative to the other first electrically conductive layer 116, to the exterior sidewall 102a of the substrate 102. The second electrically conductive layers 118 are electrically insulated from each other. The second electrically conductive layers 118 include a first electrically conductive portion 118a and a second electrically conductive portion 118b. The first electrically conductive portion 118a is formed in the third patterned trench 108c and thus has the same pattern as the third patterned trench 108c. That is, the first electrically conductive portion 118a is disposed on a central region of the bottom surface 100a of the second groove 106. The second electrically conductive portion 118b is formed in the second patterned trenches 108b and thus has the same pattern as the second patterned trenches 108b. That is, the second electrically conductive portion 118b extends from the bottom surface 100a of the second groove 106, along the interior sidewall 100b of the second groove 106, to the exterior sidewall 102a of the substrate 102. In one embodiment, the first plating layer 110 is made of copper, meaning the metal ions are copper ions, so as to aid the second plating layer 112 and the third plating layer 114 to be disposed on the substrate 102. The second plating layer 112 is made of nickel and the third plating layer 114 is made of gold. This prevents the first plating layer 110 from oxidation due to reaction with oxygen in the ambience, and aids subsequent metal wire welding and chip bonding. However, the second plating layer 112 and the third plating layer 114 are not limited to the above-identified metallic materials. The second plating layer 112 may be made of copper, tin, silver, platinum, gold, or a combination thereof. The third plating layer 114 may be made of tin, silver, platinum, gold, or a combination thereof. Additionally, the present invention is not limited to covering the first plating layer 110 with two plating layers. The present invention may carry out one electroplating process to form the second plating layer 112, such as gold for example, on the first plating layer 110. Alternatively, the present invention may carry out plural electroplating processes to form a plurality of plating layers over the first plating layer 110 with, for example, copper, tin, silver, platinum, gold, or a combination thereof. The method of forming the second plating layer 112 on the first plating layer 110 is not limited to electroplating, and may be sputtering, physical vapor deposition, etc.

Next, as shown in FIG. 6, a chip bonding process is performed. Using an electrically conductive adhesive (not shown), a light-emitting chip 120 is adhered to the substrate 102 in the first groove 104 and a sensor chip 122 is adhered to the substrate 102 in the second groove 106. Afterwards, an electrical connecting process is performed, such as wire welding for example, to electrically connect the light-emitting chip 120 between the first electrically conductive layers 116 with a plurality of first metal wires 124 and to electrically connect the sensor chip 122 to the second electrically conductive portion 118b. However, the present invention is not limited to chip bonding and wire welding processes, and may carry out a flip chip process for chip bonding and electrical connection at the same time. Then, an adhesive dispensing process is performed to form two encapsulation bodies 126, respectively disposed over the sensor chip 122 and the light-emitting chip 120 and covering the first metal wires 124, thus protecting the light-emitting chip 120, the sensor chip 122 and the first metal wires 124 from damage due to external contact. This completes the proximity sensor packaging structure 100 of the present embodiment. In one embodiment, the sensor chip 122 includes a proximity sensing device 128 and a filter coating layer 130. The proximity sensing device 128 is configured to detect the light, which carries a specific signal, emitted from the light-emitting chip 120. The filter coating layer 130, disposed on a light sensing surface of the proximity sensing device 128, is configured to filter out light other than the light produced by the light-emitting chip 122, such as infrared light, to allow the infrared light to traverse through. This allows the proximity sensing device 128 to operate without interference from external sunlight. Furthermore, the encapsulation bodies 126 in one embodiment are made of a transparent colloid such as epoxy resin, for example. In one embodiment, the light-emitting chip 120 is an LED that produces infrared light but is not limited thereto, and may be an LED of other wavelengths. Moreover, the sensor chip 122 of the present invention is not limited to the proximity sensing device 128 and may further include an ambient light sensor device that detects a light intensity in the ambience, as an integrated light sensing device.

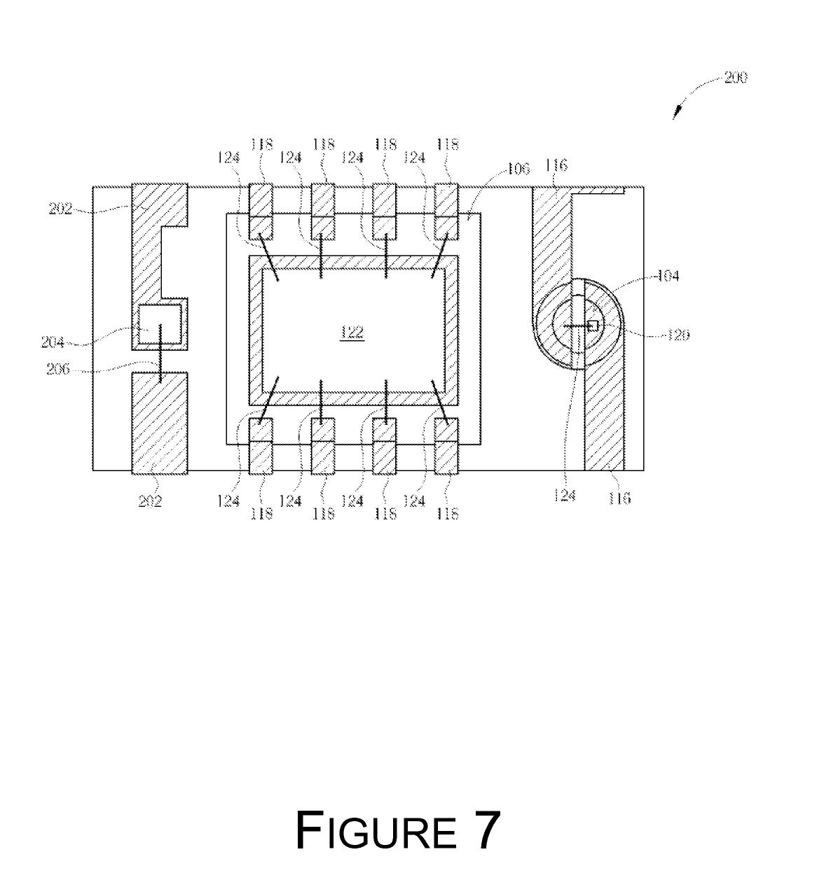

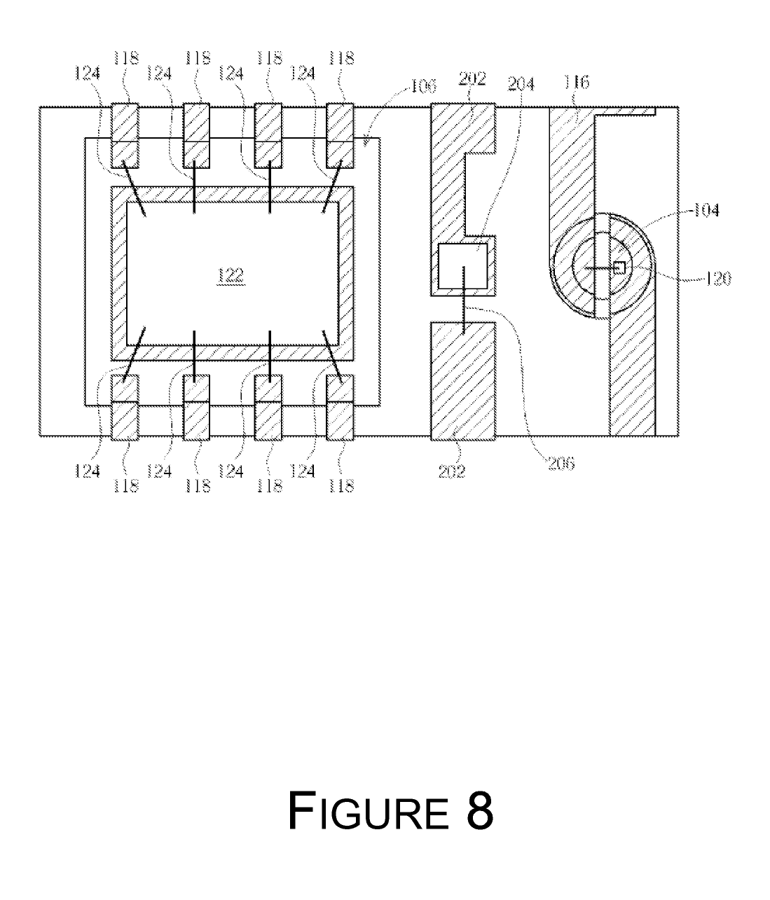

Additionally, the sensor chip 122 and the ambient light sensor device may be separate. Referring to FIG. 7, FIG. 7 is a top view diagram of a proximity sensor packaging structure in accordance with a second embodiment of the preset invention. As shown in FIG. 7, relative to the first embodiment, during the process of forming the first electrically conductive layers 116 and the second electrically conductive layers 118, the method of manufacturing a proximity sensor packaging structure 200 includes forming two third electrically conductive layers 202 on the substrate 102 on an opposite side of the second electrically conductive layers 118 relative to the first electrically conductive layers 116. During the chip bonding process, a method according to the present embodiment further includes disposing an ambient light sensor chip 204 on one of the third electrically conductive layers 202. During the electrical connection process, the method according to the present embodiment further includes electrically connecting the ambient light sensor chip 204 and the other one of the third electrically conductive layers 202 with a second metal wire 206. It is noteworthy that it is not necessary for the sensor chip 122 to include a filter coating layer, and that the encapsulation bodies 126 of the proximity sensor packaging structure 200 may be doped with a filter material to result in the encapsulation bodies 126 being a filtering encapsulant disposed on the sensor chip 122 to filter out light not produced by the light-emitting chip. In the present embodiment, the ambient light sensor chip 204 is disposed on an opposite side of the light-emitting chip 120 relative to the sensor chip 122. The present invention is not limited thereto. The ambient light sensor chip of the present invention may be disposed between the sensor chip and the light-emitting chip. Referring to FIG. 8, FIG. 8 is a top view diagram of another implementation of the proximity sensor packaging structure in accordance with the second embodiment of the present invention. As shown in FIG. 8, in one embodiment the third electrically conductive layers 202 are disposed between the first electrically conductive layers 116 and the second electrically conductive layers 118, and the ambient light sensor chip 204 is disposed on one of the third electrically conductive layers 202 and electrically connected to the third electrically conductive layers 202.

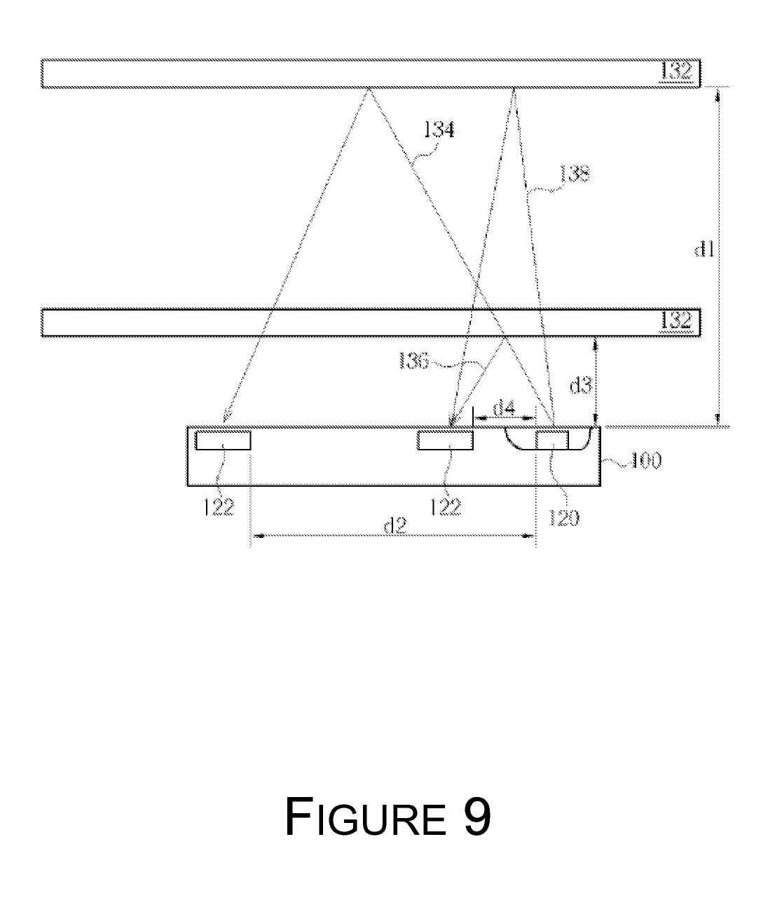

To better understand the positional relationship between the proximity sensor packaging structure of the present invention and an object to be detected as well as the relative positions of the sensor chip and the light-emitting chip, please refer to FIG. 9. FIG. 9 illustrates the relative positions of the sensor chip and the light-emitting chip when a proximity sensor packaging structure of the present invention detects objects at different distances. As shown in FIG. 9, when an object 132 approaches the proximity sensor packaging structure 100 to a point where a distance between the two is a first distance d1, the light-emitting chip 120 produces light, carrying a specific signal, that is emitted in a first specific angle along a first light path 134 and reflected by the object 132 towards the sensor chip 122, which is at a second distance d2 away from the light-emitting chip 120. When the object 132 further approaches the proximity sensor packaging structure 100 to a point where a distance between the two is a third distance d3, the light produced by the light-emitting chip 120 is emitted in the first specific angle along a second light path 136 and reflected by the object 132 towards the sensor chip 122, which is at a fourth distance d4 away from the light-emitting chip 120. By changing the focus direction of the bowl structure the produced light can be emitted in different angles. When the object 132 approaches the proximity sensor packaging structure 100 to a point where a distance between the two is the first distance d1, the light produced by the light-emitting chip 120 is emitted in a second specific angle along a third light path 138 and reflected by the object 132 towards the sensor chip 122, which is at the fourth distance d4 away from the light-emitting chip 120. Thus, changing the focus direction of the bowl structure or changing the distance between the sensor chip 122 and the light-emitting chip 120 can adjust the distance of detection between the proximity sensor packaging structure 100 and the object 132. Moreover, the position of the ambient light sensor chip can be determined after the positions of the sensor chip and the light-emitting chip are determined.

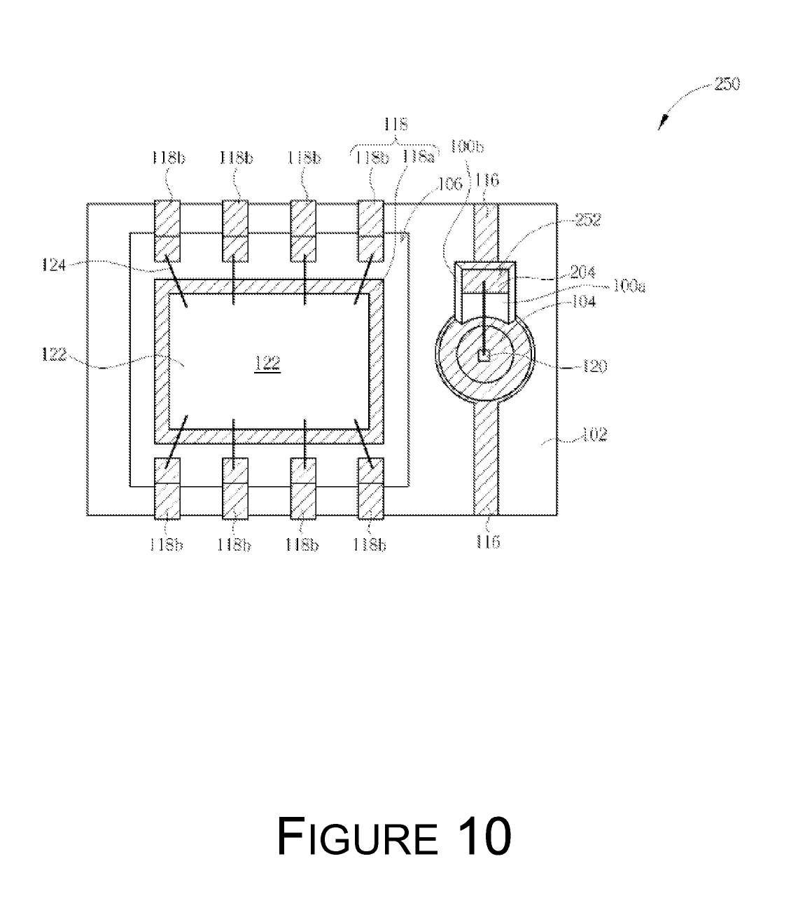

Furthermore, the substrate and the electrically conductive layers of the present invention are not limited to the embodiments described above. Referring to FIG. 10, FIG. 10 is a top view diagram of a proximity sensor packaging structure in accordance with a third embodiment of the present invention. As shown in FIG. 10, relative to the first embodiment, in the present embodiment a substrate 102 of a proximity sensor packaging structure 250 further includes a third groove 252 disposed on a side of the first groove 104. The third groove 252 extends from the interior sidewall 100b of the first groove 104 towards the upper surface of the substrate 102 to be connected with the first groove 104. Additionally, the third groove 252 is defined by the bottom surface 100a and the interior sidewall 100b that extends from the bottom surface 100a to the upper surface of the substrate 102. Moreover, one of the first electrically conductive layers 116 is disposed in the first groove 104 and completely covers the interior sidewall 100b and the bottom surface 100a. The other one of the first electrically conductive layers 116 is disposed in the third groove 252. It is noteworthy that the one of the first electrically conductive layers 116 that completely covers the interior sidewall 100b and the bottom surface 100a of the first groove 104 can be a reflective layer for the light-emitting chip 120 in the first groove 104, so as to more effectively focus the light rays emitted from the light-emitting chip 120 to enhance the light signal that is produced by the light-emitting chip 120 and detected by the sensor chip 122. Furthermore, a depth of the third groove 252 is less than a depth of the first groove 104, thus avoiding the bowl structure of the first groove 104 from losing the effect of focusing because of the third groove 252.

In summary, a manufacturing method of a proximity sensor packaging structure of the present invention forms electrically conductive layers directly on a substrate which is directly formed by laser, and embeds the electrically conductive layers on the substrate by roughening the surface of the substrate. The light-emitting chip and the sensor chip are then disposed on the substrate so that the light-emitting chip and the sensor chip are packaged in the same packaging structure to reduce the size of the proximity sensor. Additionally, due to the non-translucent characteristic of the substrate of the proximity sensor packaging structure of the present invention, erroneous detection of light emitted from the light-emitting chip and through the substrate by the sensor chip is prevented. By partly or completely covering the sidewall and bottom surface of the bowl-shaped first groove with the first electrically conductive layers to provide reflectivity, light rays emitted from the light-emitting chip disposed in the first groove can be focused by the bowl structure, thereby enhancing the signal strength of the light that is reflected from the object to be detected and detected by the sensor chip. Furthermore, as the bowl-shaped reflective layer focuses light, not only reflection of some of the emitted light by the translucent cover and reception by the sensor chip of light signal not reflected by the object to be detected can be avoided, the light signal received by the sensor chip from the light-emitting chip can also be enhanced. This improves the sensing capability of the proximity sensor packaging structure.

The above description pertains to the preferred embodiments of the present invention. Deviations and modifications based on the patent scope of the present invention are within the scope of the present invention.

1. A proximity sensor packaging structure, comprising:
a substrate having a first groove and a second groove and being non-translucent, each of the first and second grooves respectively defined by a bottom surface of the substrate and a respective interior sidewall that extends from the bottom surface to a top surface of the substrate;
two first electrically conductive layers disposed on the substrate and electrically insulated between one another, each of the first electrically conductive layers extending from a bottom surface of the first groove, along the interior sidewall of the first groove and in an opposite direction relative to the other first electrically conductive layer, to an exterior sidewall of the substrate;
a plurality of second electrically conductive layers disposed on the substrate and electrically insulated from each other, the second electrically conductive layers including a first electrically conductive portion and a second electrically conductive portion, the first electrically conductive portion disposed at a central region of a bottom surface of the second groove, the second electrically conductive portion extending from the bottom surface of the second groove along the interior sidewall of the second groove to the exterior sidewall of the substrate;
a light-emitting chip disposed in the first groove and electrically connected to the first electrically conductive layers;
a sensor chip disposed on the first electrically conductive portion of the second electrically conductive layers in the second groove and electrically connected to the second electrically conductive layers; and
two encapsulation bodies respectively disposed over the light-emitting chip and the sensor chip.

2. The proximity sensor packaging structure as recited in claim 1, wherein the substrate is made of a composite material that is configured to form the first and second electrically conductive layers on one or more surfaces of the substrate upon activation by laser irradiation.

3. The proximity sensor packaging structure as recited in claim 1, wherein the substrate further comprises a third groove that extends from the interior sidewall of the first groove to the top surface of the substrate, one of the first electrically conductive layers disposed in the first groove and the other one of the first electrically conductive layers disposed in the third groove.

4. The proximity sensor packaging structure as recited in claim 1, wherein the first electrically conductive layers completely cover the interior sidewall and the bottom surface of the first groove.

5. The proximity sensor packaging structure as recited in claim 3, wherein a depth of the third groove is less than a depth of the first groove.

6. The proximity sensor packaging structure as recited in claim 1, wherein the sensor chip includes a proximity sensing device and a filter coating layer that is disposed on the proximity sensing device, and wherein the encapsulation body disposed over the sensor chip comprises a transparent colloid.

7. The proximity sensor packaging structure as recited in claim 6, wherein the encapsulation body disposed over the sensor chip comprises a filtering encapsulant.

8. The proximity sensor packaging structure as recited in claim 1, further comprising:
two third electrically conductive layers disposed on the substrate and between the first electrically conductive layers and the second electrically conductive layers.

9. The proximity sensor packaging structure as recited in claim 8, further comprising:
an ambient light sensor chip disposed on one of the third electrically conductive layers and electrically connected to the third electrically conductive layers.

10. The proximity sensor packaging structure as recited in claim 1, further comprising:
two third electrically conductive layers disposed on the substrate and on an opposite side of the second electrically conductive layers relative to the first electrically conductive layers.

11. The proximity sensor packaging structure as recited in claim 10, further comprising:
an ambient light sensor chip disposed on one of the third electrically conductive layers and electrically connected to the third electrically conductive layers.

12. The proximity sensor packaging structure as recited in claim 1, wherein the light-emitting chip comprises a light-emitting diode (LED) chip.

13. A method of manufacturing a proximity sensor packaging structure, comprising:
providing a substrate, the substrate having a first groove and a second groove, the substrate being non-translucent;
forming a plurality of patterned trenches on one or more surfaces of the substrate such that a respective portion of the substrate in each of the patterned trenches has a rough surface;
forming two first electrically conductive layers and a plurality of second electrically conductive layers respectively on portions of the substrate in the patterned trenches;
adhering a light-emitting chip and a sensor chip to the substrate in the first groove and the second groove, respectively;
electrically connecting the light-emitting chip between the first electrically conductive layers; and
electrically connecting the sensor chip to the second electrically conductive layers.

14. The method as recited in claim 13, wherein the substrate is made of a composite material that is configured to form the first and second electrically conductive layers on one or more surfaces of the substrate upon activation by laser irradiation.

15. The method as recited in claim 13, wherein the forming a plurality of patterned trenches on one or more surfaces of the substrate comprises activating the one or more surfaces of the substrate by laser irradiation.

16. The method as recited in claim 13, wherein the forming two first electrically conductive layers and a plurality of second electrically conductive layers comprises:
performing a chemical plating process to form a first plating layer on portions of the substrate that are in the patterned trenches; and
performing an electroplating process to form at least one second plating layer on the first plating layer, wherein the first and second electrically conductive layers are constructed of the first plating layer and the second plating layer.

17. The method as recited in claim 13, wherein, after electrically connecting the light-emitting chip between the first electrically conductive layers and electrically connecting the sensor chip to the second electrically conductive layers, the method further comprises:
performing an adhesive dispensing process to form two encapsulation bodies disposed over the light-emitting chip and the sensor chip, respectively.

18. The method as recited in claim 13, wherein the first groove comprises a bowl-shaped groove.

19. The method as recited in claim 13, further comprising:
disposing two encapsulation bodies over the light-emitting chip and the sensor chip, respectively,
wherein the encapsulation body disposed over the sensor chip comprises a filtering encapsulant.

20. The method as recited in claim 13, further comprising:
forming two third electrically conductive layers on the substrate;
disposing an ambient light sensor chip on one of the third electrically conductive layers; and
electrically connecting the ambient light sensor chip to the third electrically conductive layers.
